(19) United States
(12) Patent Application Publication
(10) Pub. No.: US 2026/0013130 A1
(43) Pub. Date: Jan. 8, 2026

(54) SEMICONDUCTOR STORAGE DEVICE AND MANUFACTURING METHOD THEREOF

(71) Applicant: Kioxia Corporation, Minato-ku (JP)

(72) Inventor: Mio SHINKAI, Yokkaichi Mie (JP)

(73) Assignee: Kioxia Corporation, Minato-ku (JP)

(21) Appl. No.: 18/970,499

(22) Filed: Dec. 5, 2024

(30) Foreign Application Priority Data
Jul. 2, 2024 (JP) 2024-107038

(51) Int. Cl. H10B 43/27; H01L 23/00; H01L 25/065; H01L 25/18; H10B 80/00

(52) U.S. Cl. CPC H10B 43/27; H01L 24/08; H01L 25/0657; H01L 25/18; H10B 80/00; H01L 2224/08145; H01L 2924/1431; H01L 2924/14511

(57) ABSTRACT

A memory includes a stacked body including electrode layers and first insulating layers stacked in a first direction. Each of a plurality of first columnar bodies includes a semiconductor layer located to penetrate through the stacked body in the first direction. A source is connected to an end part of the semiconductor layer on a side of one end of the semiconductor layer. A pillar portion is located to extend in the first direction in the stacked body, or in a structure located alongside the stacked body in a second direction, and includes a carbon material. A cap portion is located at an end part of the pillar portion on a side of another end out of one end and another end of the pillar portion respectively corresponding to the one end and another end of the semiconductor layer, and includes a first material having an etching-selectivity to the carbon material and the first insulating films.

### CROSS REFERENCE TO RELATED APPLICATIONS

This application is based upon and claims the benefit of priority from the prior Japanese Patent Application No. 2024-107038, filed on Jul. 2, 2024, the entire contents of which are incorporated herein by reference.

### FIELD

The embodiments of the present invention relate to a semiconductor storage device and manufacturing method thereof.

### BACKGROUND

Some of semiconductor storage devices such as a NAND flash memory have a three-dimensional memory cell array in which a plurality of memory cells are arranged three-dimensionally. At the time of formation of memory holes in a stacked structure, a sacrificial film is temporarily embedded in the memory holes of the stacked structure in some cases.

If this sacrificial film has a seam or a void, there is a risk that, for example, a material having entered the seam or void unintentionally remains in the memory holes.

### BRIEF DESCRIPTION OF THE DRAWINGS

FIG. 1 is a sectional view illustrating a configuration example of a semiconductor storage device according to a first embodiment;

FIG. 2 is a plan view illustrating a stacked body;

FIG. 3 is a sectional view illustrating an example of memory cells of a three-dimensional structure;

FIG. 4 is a sectional view illustrating an example of the memory cells of a three-dimensional structure;

FIG. 5A is a sectional view illustrating a configuration example of an array chip according to the first embodiment;

FIG. 5B is a plan view illustrating a configuration example of the array chip according to the first embodiment;

FIG. 6A is a sectional view illustrating an example of a manufacturing method of a semiconductor storage device according to the first embodiment;

FIG. 6B is a sectional view illustrating an example of the manufacturing method subsequent to FIG. 6A;

FIG. 7 is a sectional view illustrating an example of the manufacturing method subsequent to FIG. 6B;

FIG. 8 is a sectional view illustrating an example of the manufacturing method subsequent to FIG. 7;

FIG. 9A is a sectional view illustrating an example of the manufacturing method subsequent to FIG. 8;

FIG. 9B is a sectional view illustrating an example of the manufacturing method subsequent to FIG. 9A;

FIG. 10 is a sectional view illustrating an example of the manufacturing method subsequent to FIG. 9B;

FIG. 11 is a sectional view illustrating an example of the manufacturing method subsequent to FIG. 10;

FIG. 12 is a sectional view illustrating an example of the manufacturing method subsequent to FIG. 11;

FIG. 13 is a sectional view illustrating an example of the manufacturing method subsequent to FIG. 12;

FIG. 14A is a sectional view illustrating an example of the manufacturing method subsequent to FIG. 13;

FIG. 14B is a sectional view illustrating an example of the manufacturing method subsequent to FIG. 14A;

FIG. 15 is a sectional view illustrating an example of the manufacturing method subsequent to FIG. 14B;

FIG. 16 is a sectional view illustrating the manufacturing method of a semiconductor storage device in a case where a cap film is not used;

FIG. 17 is a sectional view illustrating the manufacturing method subsequent to FIG. 16;

FIG. 18 is a sectional view illustrating the manufacturing method subsequent to FIG. 17;

FIG. 19 is a sectional view illustrating the manufacturing method subsequent to FIG. 18;

FIG. 20 is a sectional view illustrating the manufacturing method subsequent to FIG. 19;

FIG. 21 is a sectional view illustrating an example of the manufacturing method of a semiconductor storage device in a case where the cap film according to the first embodiment is used;

FIG. 22 is a sectional view illustrating an example of the manufacturing method subsequent to FIG. 21;

FIG. 23 is a sectional view illustrating the manufacturing method of a semiconductor storage device in a case where a cap film is not used for formation of a second stacked portion;

FIG. 24 is a sectional view illustrating the manufacturing method subsequent to FIG. 23;

FIG. 25 is a sectional view illustrating the manufacturing method subsequent to FIG. 24;

FIG. 26 is a sectional view illustrating an example of the manufacturing method of a semiconductor storage device in a case where the cap film according to the first embodiment is used;

FIG. 27 is a sectional view illustrating an example of the manufacturing method subsequent to FIG. 26;

FIG. 28 is a sectional view illustrating a configuration example of an array chip according to a second embodiment;

FIG. 29 is a sectional view illustrating a configuration example of an array chip according to a third embodiment;

FIG. 30 is a sectional view illustrating a configuration example of an array chip according to a fourth embodiment; and

FIG. 31 is a sectional view illustrating a configuration example of an array chip according to a fifth embodiment.

### DETAILED DESCRIPTION

In general, according to the embodiment, a semiconductor storage device includes a stacked body including a plurality of electrode films and a plurality of first insulating films alternately stacked in a first direction. Each of a plurality of first columnar bodies includes a semiconductor layer located to penetrate through the stacked body in the first direction and forms a memory cell at an intersecting portion with one of the electrode films. A source layer is electrically connected to an end part of the semiconductor layer on a side of one end out of one end and another end of the semiconductor layer in the first direction. A pillar portion is located to extend in the first direction in the stacked body, or in a structure located alongside the stacked body in a second direction intersecting with the first direction, and includes a carbon material. A cap portion is located at an end part of the pillar portion on a side of another end out of one end and another end of the pillar portion respectively corresponding to the one end and the other end of the semiconductor layer in the first direction, and includes a first material having an etching selectivity to at least the carbon material and the first insulating films. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

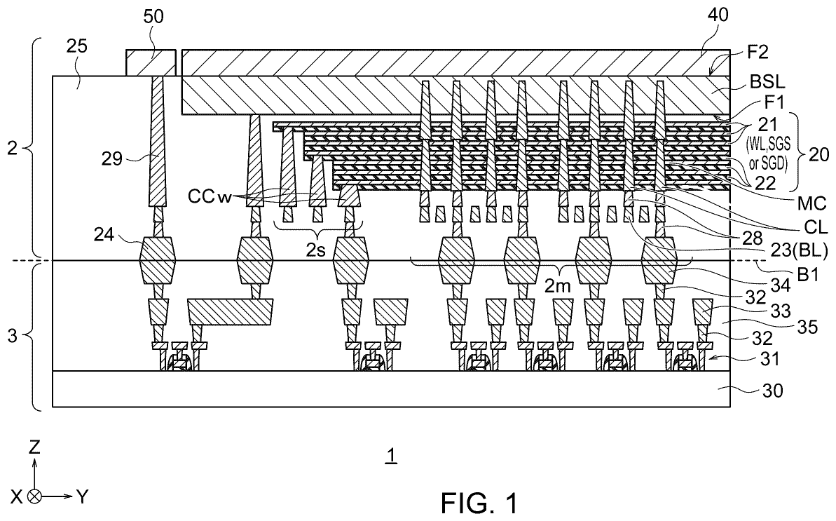

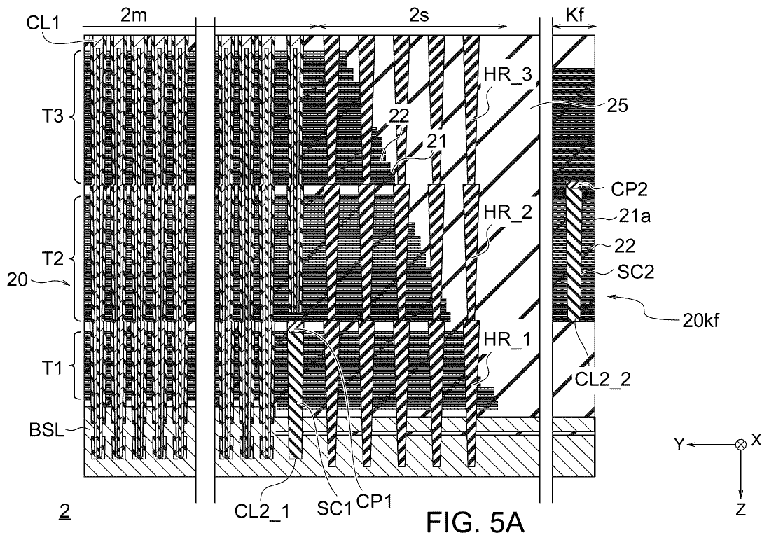

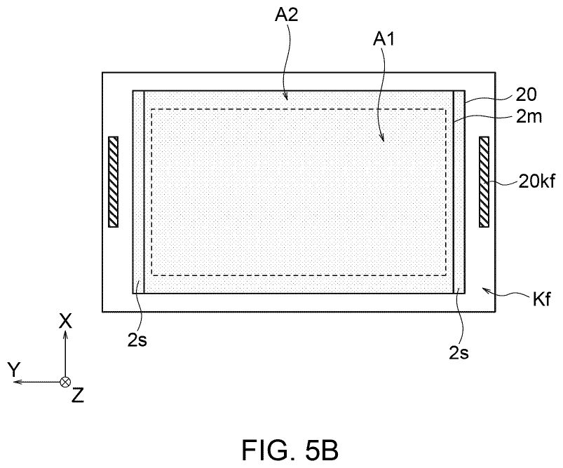

FIG. 1 is a sectional view illustrating a configuration example of a semiconductor storage device 1 according to a first embodiment. Hereinafter, the stacking direction of a stacked body 20 is assumed as a Z direction. One direction intersecting with, for example, being orthogonal to the Z direction is assumed as a Y direction. One direction intersecting with, for example, being orthogonal to the Z direction and the Y direction is assumed as an X direction. In FIG. 1, the semiconductor storage device 1 is illustrated with the +Z direction as upward. In a sectional view of FIG. 5A and subsequent sectional views, an array chip is illustrated with the −Z direction as upward. In the present specification, the ±Z directions are examples of a first direction.

The semiconductor storage device 1 includes an array chip 2 having a memory cell array, and a CMOS (Complementary Metal Oxide Semiconductor) chip 3 having a CMOS circuit. The array chip 2 and the CMOS chip 3 are bonded to each other on a bonding face B1 and are electrically connected to each other with lines joined on the bonding face B1. FIG. 1 illustrates a state in which the array chip 2 is located on the CMOS chip 3.

The CMOS chip 3 includes a substrate 30, transistors 31, vias 32, lines 33 and 34, and an interlayer dielectric film 35.

The substrate 30 is, for example, a semiconductor substrate such as a silicon substrate. The transistors 31 are an N-type MOSFET (MOS Field Effect Transistor) or a P-type MOSFET provided on the substrate 30. For example, transistors 31 constitute a CMOS circuit that controls a memory cell array 2m of the array chip 2. A plurality of the transistors 31 constitute logic circuits such as a sense amplifier, a row decoder, and a column decoder. Semiconductor elements such as a resistive element and a capacitive element, other than the transistors 31 may be formed on the substrate 30.

Each of the vias 32 electrically connects between a transistor 31 and a line 33 or between a line 33 and a line 34. The lines 33 and 34 constitute a multilayer wiring structure in the interlayer dielectric film 35. The lines 34 are embedded in the interlayer dielectric film 35 and are exposed on the surface of the interlayer dielectric film 35 to be substantially flush with the surface. The lines 33 and 34 are electrically connected to the transistors 31 and the like. For example, a metal such as copper or tungsten is used as the vias 32, and the lines 33 and 34. The interlayer dielectric film 35 coats and protects the transistors 31, the vias 32, and the lines 33 and 34. For example, an insulating film such as a silicon dioxide film is used as the interlayer dielectric film 35.

The array chip 2 includes the stacked body 20, columnar bodies CL, a source layer BSL, a metallic layer 40, contact plugs CCw, contact plugs 29, bonding pads 50, lines 23 and 24, vias 28, and an interlayer dielectric film 25.

The stacked body 20 is provided above the transistors 31 and is positioned in the +Z direction with respect to the substrate 30. The stacked body 20 is configured by alternately stacking a plurality of electrode films 21 and a plurality of insulating films 22 along the Z direction. The stacked body 20 constitutes the memory cell array with the columnar bodies CL. For example, a conductive metal such as tungsten is used as the electrode films 21. For example, a silicon dioxide film is used as the insulating films 22. The insulating films 22 insulate the electrode films 21 from each other. That is, the electrode films 21 are stacked in a mutually insulated state. The numbers of stacked layers of the electrode films 21 and the insulating films 22 can be freely selected. The insulating films 22 may be, for example, porous insulating films or air gaps.

Ones or pluralities of the electrode films 21 at the upper end and the lower end of the stacked body 20 in the Z direction function as source-side selection gates SGS and drain-side selection gates SGD, respectively. Electrode films 21 between the source-side selection gates SGS and the drain-side selection gates SGD function as word lines WL. The word lines WL are gate electrodes of memory cells MC. The source-side selection gates SGS are gate electrodes of source-side selection transistors. The drain-side selection gates SGD are gate electrodes of drain-side selection transistors. The source-side selection gates SGS are provided in an upper region of the stacked body 20. The drain-side selection gates SGD are provided in a lower region of the stacked body 20. The upper region indicates a region of the stacked body 20 on a side far from the CMOS chip 3 (a side close to the metallic layer 40), and the lower region indicates a region of the stacked body 20 on a side close to the CMOS chip 3.

The semiconductor storage device 1 includes a plurality of memory cells MC connected in series between each of the source-side selection transistors and an associated drain-side selection transistor. A structure in which a source-side selection transistor, memory cells MC, and a drain-side selection transistor are connected in series is referred to as “memory string” or “NAND string”. A memory string is, for example, connected to a bit line BL through a via 28. The bit lines BL are the lines 23 provided below the stacked body 20 and extending in the X direction. Therefore, hereinafter, the bit lines BL are hereinafter referred to also as “bit lines 23”.

A plurality of columnar bodies CL are provided in the stacked body 20. The columnar bodies CL extend in the stacked body 20 to penetrate through the stacked body 20 in the stacking direction (the Z direction) of the stacked body 20 and are each located from a via 28 connected to a bit line 23 to the source layer BSL. An internal structure of the columnar bodies CL will be described later. FIG. 1 illustrates the columnar bodies CL formed in two tiers in the Z direction. However, it is permissible that the columnar bodies CL are formed in three or more tiers as illustrated in FIG. 5A.

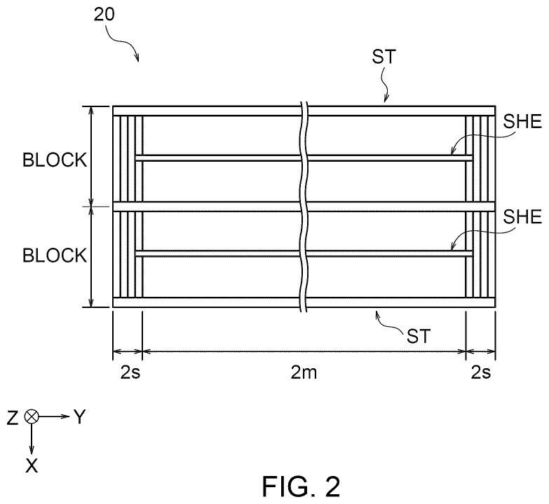

Although not illustrated in FIG. 1, a plurality of slits ST (see FIG. 2) are provided in the stacked body 20. The slits ST extend in the Y direction and penetrate through the stacked body 20 in the stacking direction (the Z direction) of the stacked body 20. An insulating film such as a silicon dioxide film is filled in each of the slits ST and the insulating film is configured in a plate shape. The slits ST electrically divide the electrode films 21 of the stacked body 20. It is alternatively possible that the inner wall of each of the slits ST is coated with an insulating film such as a silicon dioxide film and that a conductive material is further embedded in the inner side of the insulating film. In this case, the conductive material can also function as a source line reaching the source layer BSL.

The source layer BSL is provided on the stacked body 20. The source layer BSL is provided corresponding to the stacked body 20. The stacked body 20 (the memory cell array 2m) is located on the side of a face F1 of the source layer BSL, and the metallic layer 40 is located on the side of a face F2 opposite to the face F1. The source layer BSL is connected in common to one ends of the columnar bodies CL and provides the columnar bodies CL in the same memory cell array 2m with a common source voltage. That is, the source layer BSL functions as a common source electrode of the memory cell array 2m. For example, a conductive material such as doped polysilicon is used as the source layer BSL. For example, a metallic material of a lower resistance than that of the source layer BSL, such as copper, aluminum, or tungsten is used as the metallic layer 40.

Meanwhile, the bonding pads 50 are provided in a region that is above the face F2 of the source layer BSL and where the source layer BSL is not located. The bonding pads 50 are connected to metallic wires or the like (not illustrated) and receive power supply or signals from outside the semiconductor storage device 1. The bonding pads 50 are provided so as to be connected to one ends of the contact plugs 29 in the Z direction. The bonding pads 50 are connected to the transistors 31 of the CMOS chip 3 via the contact plugs 29, the lines 24, and the lines 34. External power supplied from the bonding pads 50 is supplied to the transistors 31. Alternatively, signals are supplied to the transistors 31 via the bonding pads 50.

The contact plugs CCw are provided in a peripheral part of the stacked body 20 and extend in the Z direction in the interlayer dielectric film 25. Each of the contact plugs CCw is electrically connected between an electrode film 21 (a word line WL) and a line 24. The contact plugs CCw are provided at stepped portions 2s where the electrode films 21 are formed like stairs at end parts of the stacked body 20 and are each electrically connected to an associated electrode film 21. The contact plugs CCw are provided to transmit a word line voltage from the CMOS chip 3 to the associated electrode films 21. For example, a metal such as copper or tungsten is used as the contact plugs CCw.

The contact plugs 29 are provided in a peripheral part of the stacked body 20 and extend in the Z direction in the interlayer dielectric film 25. The contact plugs 29 are provided at least from a side lower than the stacked body 20 to a side higher than the stacked body 20.

Each of the contact plugs 29 is electrically connected between a bonding pad 50 and a line 24. The contact plugs 29 are used to supply power or a signal from the bonding pads 50 to the array chip 2 or the CMOS chip 3. For example, a metal such as copper or tungsten is used as the contact plugs 29. The power is, for example, a power voltage VDD or a reference voltage (for example, a ground voltage) VSS lower than the power voltage VDD. The signal may be a control signal from outside, or may be data to be written or read.

In the present embodiment, the array chip 2 and the CMOS chip 3 are individually formed and are bonded to each other on the boding face B1. Therefore, the transistors 31 are not provided in the array chip 2. The stacked body 20 (the memory cell array 2m) is not provided in the CMOS chip 3.

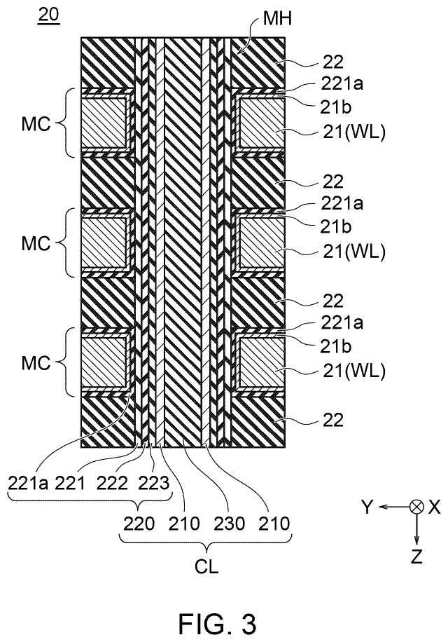

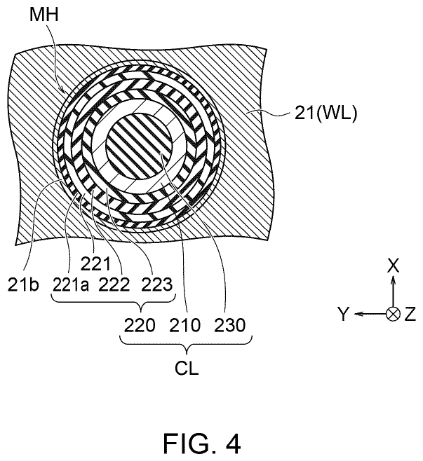

The vias 28, the lines 23, and the lines 24 are provided below the stacked body 20. The lines 23 and 24 are embedded in the interlayer dielectric film 25. The lines 24 are exposed on the surface of the interlayer dielectric film 25 to be substantially flush with the surface. The lines 23 and 24 are electrically connected to semiconductor bodies (210 in FIGS. 3 and 4) of the columnar bodies CL, and the like. For example, a metal such as copper or tungsten is used as the vias 28, the lines 23, and the lines 24. The interlayer dielectric film 25 coats and protects the stacked body 20, the vias 28, the lines 23, and the lines 24. For example, an insulating film such as a silicon dioxide film is used as the interlayer dielectric film 25.

The interlayer dielectric film 25 and the interlayer dielectric film 35 are bonded to each other on the bonding face B1. Associated therewith, the lines 24 and the lines 34 are joined to each other on the bonding face B1 to be substantially flush therewith. Accordingly, the array chip 2 and the CMOS chip 3 are electrically connected to each other via the lines 24 and the lines 34.

FIG. 2 is a plan view illustrating the stacked body 20. The stacked body 20 includes the stepped portions 2s and the memory cell array 2m. The stepped portions 2s are located, for example, at end parts of the stacked body 20. The memory cell array 2m is sandwiched or surrounded by the stepped portions 2s. The slits ST are provided from the stepped portion 2s at one end of the stacked body 20 through the memory cell array 2m to the stepped portion 2s at the other end of the stacked body 20. Slits SHE are provided at least on the memory cell array 2m. The slits SHE are shallower in the Z direction than the slits ST and extend substantially in parallel to the slits ST. The slits SHE electrically divide electrode films 21 on the side of a lower region of the stacked body 20 for each of the drain-side selection gates SGD. For example, an insulating film such as a silicon dioxide film is used as the slits SHE. The slits ST may include source lines electrically isolated from the electrode films 21 of the stacked body 20 and electrically connected to the source layer BSL.

A portion of the stacked body 20 sandwiched by two slits ST illustrated in FIG. 2 is referred to as “block (BLOCK)”. A block constitutes, for example, a minimum unit of data erasing. A slit SHE is provided in each block. The stacked body 20 between a slit ST and a slit SHE is referred to as “finger”. The drain-side selection gates SGD are separated for each finger. Accordingly, at the time of writing and reading data, one finger in one block can be brought to a selected state by the associated drain-side selection gate SGD.

FIGS. 3 and 4 are sectional views illustrating an example of memory cells of a three-dimensional structure. The columnar bodies CL are each provided in a memory hole MH formed in the stacked body 20. Each of the columnar bodies CL penetrates through the stacked body 20 along the Z direction from one end part of the stacked body 20 to be provided in the stacked body 20 and the source layer BSL. Each of the columnar bodies CL includes the semiconductor body 210, a memory film 220, and a core layer 230. Each columnar body CL includes the core layer 230 located at a central part thereof, the semiconductor body (a semiconductor layer) 210 located around the core layer 230, and the memory film 220 located around the semiconductor body 210. The semiconductor body 210 extends in the stacked body 20 in the stacking direction (the Z direction). The semiconductor body 210 is electrically connected to the source layer BSL. The memory film 220 is located between the semiconductor body 210 and the electrode films 21 and has charge capturing parts. A plurality of the columnar bodies CL each selected from each finger are connected in common to one bit line 23 through the vias 28 in FIG. 1. Each of the columnar bodies CL is provided, for example, in a region of the memory cell array 2m.

As illustrated in FIG. 4, the shape of each of the memory holes MH in an X-Y plane is, for example, circular or elliptic. A block dielectric film 221a constituting a part of the memory film 220 may be provided between each of the electrode films 21 and adjacent insulating films 22. The block dielectric film 221a is, for example, a silicon oxide or a metal oxide. One example of the metal oxide is an aluminum oxide. A barrier film 21b may be provided between each of the electrode films 21 and adjacent insulating films 22 and between each of the electrode films 21 and the memory film 220. The barrier film 21b is, for example, a titanium nitride, for example, in a case in which the electrode films 21 are tungsten. The block dielectric film 221a suppresses back tunneling of charges from the electrode films 21 to the memory film 220. The barrier film 21b enhances adhesion between the electrode films 21 and the block dielectric film 221a.

The shape of the semiconductor body 210 is, for example, a bottomed tube. For example, polysilicon is used as the semiconductor body 210. The semiconductor body 210 is, for example, undoped silicon. The semiconductor body 210 may be p-type silicon. The semiconductor body 210 functions as channels of the drain-side selection transistors, the memory cells MC, and the source-side selection transistors. That is, a plurality of the memory cells MC each have a storage region between the semiconductor body 210 and an electrode film 21 functioning as a word line WL and are stacked in the Z direction. One ends of a plurality of the semiconductor bodies 210 in the same memory cell array 2m are electrically connected in common to the source layer BSL.

The memory film 220 includes, for example, a cover dielectric film 221, a charge capturing film 222, a tunnel dielectric film 223, and the block dielectric film 221a. A portion of the memory film 220 other than the block dielectric film 221a is located between the inner wall of the memory hole MH and the semiconductor body 210. The shape of the memory film 220 is, for example, tubular. Each of the charge capturing film 222 and the tunnel dielectric film 223 extends in the Z direction.

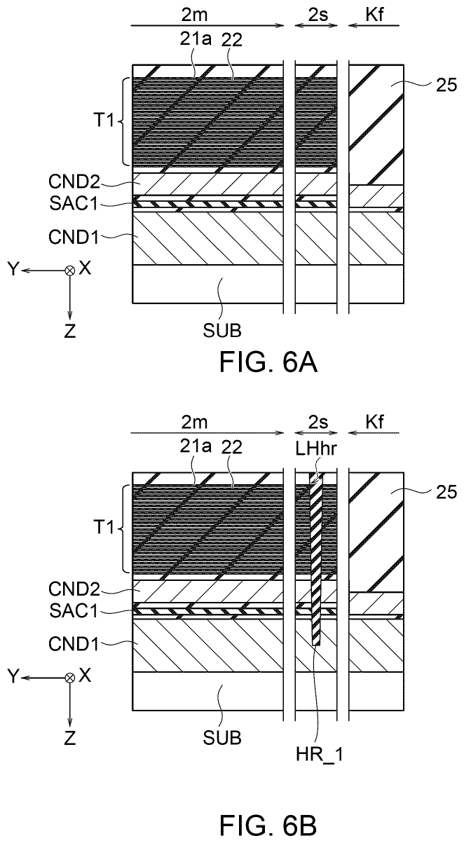

The cover dielectric film 221 is located between the insulating films 22 and the charge capturing film 222 and between the block dielectric film 221a and the charge capturing film 222. The cover dielectric film 221 includes, for example, a silicon oxide. The cover dielectric film 221 protects the charge capturing film 222 from being etched when sacrificial films (21a in FIG. 6A) are replaced by the electrode films 21 (in a replacement process).

The charge capturing film 222 is located between the cover dielectric film 221 and the tunnel dielectric film 223. The charge capturing film 222 includes, for example, a silicon nitride and has a trap site that traps charges in the film. Portions of the charge capturing film 222 sandwiched between the electrode films 21 functioning as the word lines WL and the semiconductor body 210 constitute the storage regions of the memory cells MC as the charge capturing parts. A threshold voltage of each of the memory cells MC varies according to whether there are charges in the associated charge capturing part or the amount of charges captured in the charge capturing part. Accordingly, each of the memory cells MC retains information.

The tunnel dielectric film 223 is located between the semiconductor body 210 and the charge capturing film 222. The tunnel dielectric film 223 includes, for example, a silicon oxide, or a silicon oxide and a silicon nitride. The tunnel dielectric film 223 is a potential barrier between the semiconductor body 210 and the charge capturing film 222. For example, when electrons are injected from the semiconductor body 210 to the charge capturing film 222 (a write operation) and when positive holes are injected from the semiconductor body 210 to the charge capturing film 222 (an erase operation), the electrons and the positive holes each pass through (tunnel) the potential barrier of the tunnel dielectric film 223.

The core layer 230 fills the internal space of the tubular semiconductor body 210. The shape of the core layer 230 is, for example, columnar. The core layer 230 includes, for example, a silicon oxide and is insulating.

FIG. 5A is a sectional view illustrating a configuration example of the array chip 2 according to the first embodiment. FIG. 5B is a plan view illustrating the configuration example of the array chip 2 according to the first embodiment. In the sectional view of FIG. 5A and subsequent sectional views, the array chip 2 is illustrated with the −Z direction as upward for the sake of convenience. The stacked body 20 is provided in three tiers including a first stacked portion T1 to a third stacked portion T3 in the Z direction. In FIG. 5A, the memory cell array 2m, the stepped portion 2s, and a kerf region Kf are illustrated alongside. The kerf region Kf is an outer edge region around the stacked body 20 where the memory cell array 2m is located, and is a region corresponding to a dicing line between adjacent chips in a semiconductor wafer as illustrated in FIG. 5B. While the kerf region Kf is a region eliminated from a chip at the time of cutting in a dicing process, a part of the kerf region Kf sometimes remains on the chip as illustrated in FIG. 5B.

In FIG. 5B, a first region A1 is a region where a plurality of first columnar bodies CL1 constituting effective memory cells are arranged regularly in the stacked body 20. The effective memory cells function effectively as memory cells MC that are capable of retaining information. A second region A2 is a region outside the first region A1 in the stacked body 20 and is a region where a plurality of first columnar bodies CL1 constituting dummy memory cells are arranged. The dummy memory cells do not function as memory cells MC that are capable of retaining information and are provided to surely form the effective memory cells. The stepped portion 2s is provided at both end parts of the memory cell array 2m in the Y direction. In FIG. 5B, structures 20kf are stacked bodies of the sacrificial films 21a and the insulating films 22 as illustrated in FIG. 5A and are provided, for example, to be embedded in the interlayer dielectric film 25 in the kerf region Kf.

The array chip 2 includes the source layer BSL, the first to third stacked portions T1 to T3, first columnar bodies CL1, second columnar bodies CL2_1 and CL2_2, supporting columns HR_1 to HR_3, and the interlayer dielectric film 25.

The first to third stacked portions T1 to T3 each have a stacked structure of the electrode films 21 and the insulating films 22 above the source layer BSL and constitute the stacked body 20. The first stacked portion T1 is located between the source layer BSL and the second stacked portion T2. The second stacked portion T2 is located between the first stacked portion T1 and the third stacked portion T3. In the present embodiment, the third stacked portion T3 is the uppermost portion of the stacked body 20. The first to third stacked portions T1 to T3 are stacked in the Z direction and memory holes are individually formed in each of the first to third stacked portions T1 to T3. The first columnar bodies CL1 are provided to penetrate through the first to third stacked portions T1 to T3 in the Z direction.

The first columnar bodies CL1 each have the configuration of the columnar body CL explained with reference to FIGS. 3 and 4. One end of each of the first columnar bodies CL1 in the +Z direction reaches the source layer BSL and an end part of the semiconductor body 210 at the end of the first columnar body CL is electrically connected to the source layer BSL. A memory cell MC is provided corresponding to an intersecting portion between each of first columnar bodies CL1 and each of the electrode films 21 of the first to third stacked portions T1 to T3.

The second columnar bodies CL2_1 each include a pillar portion SC1 extending in the first stacked body T1 in the Z direction. The pillar portion SC1 includes, for example, carbon as a material. There is a depressed area at one end of the pillar portion SC1 in the −Z direction and a cap film (a cap portion) CP1 including a first material is provided on the depressed area. The cap film CP1 may be in contact with the electrode films 21 and the insulating films 22 of the first stacked portion T1. The second columnar bodies CL2_1 each including the pillar portion SC1 and the cap film CP1 penetrate through the first stacked portion T1 in the Z direction. The cap film CP1 is constituted of a material being higher in the density than at least the pillar portion SC1 (for example, carbon) and the insulating films 22 (for example, a silicon oxide), or having an etching selectivity to at least the pillar portion SC1 and the insulating films 22. A material having an etching selectivity means a material that has an etching resistance to another material or, conversely, that can be selectively etched with respect to another material. The cap film CP1 is constituted of a material being higher in the density than sacrificial films (21a in FIG. 6A) (for example, a silicon nitride) before formation of the electrode films 21 (before the replacement process), or having an etching selectivity to the sacrificial films. For example, the cap film CP1 includes any material of a metal, a metallic compound, a semiconductor, and ceramics. More specifically, the cap film CP1 includes any material of, for example, amorphous silicon and polysilicon as a semiconductor, for example, BC as ceramics, any material of, for example, W and Mo as a metal, or any material of, for example, WC, WBC, TiN, MoC, and AIO as a metallic compound. As will be described later, with the cap film CP1, it is possible to suppress an unintended material from entering in the memory holes and to suppress such a material from remaining in the memory holes even if there is a seam or a void in the pillar portion SC1.

The second columnar bodies CL2_1 are formed in memory holes formed in the first stacked portion T1. The memory holes for the second columnar bodies CL2_1 are formed at the same time as the memory holes for the first columnar bodies CL1. However, the memory holes for the second columnar bodies CL2_1 are not communicated with memory holes in the second stacked portion T2 located immediately thereabove. Therefore, the first columnar bodies CL1 are not formed in the memory holes for the second columnar bodies CL2_1 and the pillar portion SC1 and the cap film CP1 remain therein. While memory cells MC are not formed on the second columnar bodies CL2_1, memory cells MC are formed on other first columnar bodies CL1. In this way, the second columnar bodies CL2_1 can be left in the memory cell array 2m where the first columnar bodies CL1 are provided.

In the memory cell array 2m, in order to reliably open memory holes for the effective memory cells in the first region A1 illustrated in FIG. 5B, dummy memory cells are formed in the second region A2 outside the first region A1 in some cases. The second columnar bodies CL2_1 are highly likely to be generated in the second region A2 where there are the dummy memory cells due to process variation. There is a case where the second columnar bodies CL2_1 are generated, for example, in the first region A1 close to the second region A2.

The second columnar bodies CL2_2 are provided in at least a part of the kerf region Kf as an outer edge region around the memory cell array 2m. The second columnar bodies CL2_2 are located in the structures 20kf provided in the kerf region Kf. The structures 20kf are stacked bodies each including the sacrificial films 21a as second insulating films left in the kerf region Kf and the insulating films 22 as the first insulating films. The sacrificial films 21a are films before being replaced with the electrode films 21. Each of the second columnar bodies CL2_2 includes a pillar portion SC2 extending in the structure 20kf in the Z direction. The pillar portion SC2 includes, for example, carbon as a material. There is a depressed area at one end of the pillar portion SC2 in the −Z direction and a cap film CP2 including a second material is provided on the depressed area. The cap film CP2 is in contact with the sacrificial films 21a and the insulating films 22 of the structure 20kf. The second columnar bodies CL2_2 each including the pillar portion SC2 and the cap film CP2 penetrate through the structures 20kf in the Z direction. The cap film CP2 is constituted of a material being higher in the density than at least the pillar portion SC2 (for example, carbon) and the insulating films 22 (for example, a silicon oxide), or having an etching selectivity to at least the pillar portion SC2 and the insulating films 22. The cap film CP2 is constituted of a material being higher in the density than the sacrificial films 21a (for example, a silicon nitride) before formation of the electrode films 21 (before the replacement process), or having an etching selectivity to the sacrificial films 21a. For example, the cap film CP2 includes any material of a metal, a metallic compound, a semiconductor, and ceramics similarly to the cap film CP1. More specifically, the cap film CP2 includes any material of, for example, amorphous silicon, polysilicon, BC, WC, WBC, W, TiN, Mo, MoC, and AIO. As will be described later, the cap film CP2 can suppress the pillar portion SC2 from being inclined in the hole even when the pillar portion SC2 shrinks due to annealing.

The second columnar bodies CL2_2 are formed in the kerf region Kf located alongside the second stacked portion T2 in the X or Y direction. Holes for the second columnar bodies CL2_2 are formed at the same time as the memory holes for the first columnar bodies CL1 in the second stacked portion T2. However, the holes for the second columnar bodies CL2_2 are formed to provide alignment marks in the structures 20kf. Therefore, it is possible that holes are not provided immediately above or below the holes for the second columnar bodies CL2_2. The first columnar bodies CL1 are not formed in the holes for the second columnar bodies CL2_2 and the pillar portion SC2 and the cap film CP2 are left therein. While the structures 20kf in the kerf region Kf are stacked bodies each including the sacrificial films 21a and the insulating films 22, the structures 20kf may have the same configuration (a stacked body including the electrode films 21 and the insulating films 22) as that of the second stacked portion T2 in the memory cell array 2m. That is, the sacrificial films 21a of the second stacked portion T2 in the kerf region Kf may be replaced by the electrode films 21 in the replacement process, or it is possible that the sacrificial films 21a are not replaced by the electrode films 21. In FIG. 5A, memory cells MC are not formed on the second columnar bodies CL2_2. In this way, the second columnar bodies CL2_2 can be provided in the structures 20kf in the kerf region Kf.

The second columnar bodies CL2_2 may be provided in the kerf region Kf around the memory cell array 2m in the ±X and ±Y directions so as to surround the memory cell array 2m when seen in the Z direction, and alternatively may be provided at a part thereof as illustrated in FIG. 5B. Since the kerf region Kf is cut in the dicing process, there is a case where the kerf region Kf is not left around the array chip 2.

The second columnar bodies CL2_1 are not provided in the third stacked portion T3 being the uppermost stacked portion in the stacked body 20. Since the material of the first columnar bodies CL1 is deposited in memory holes for the third stacked portion T3 in a process immediately after formation of the memory holes, it is unnecessary to fill the memory holes with the sacrificial material and the first material of the cap film. That is, in a case where a plurality of the electrode films 21 and a plurality of the insulating films 22 stacked in the Z direction are not included in the −Z direction of the third stacked portion T3 (on the opposite side of the third stacked portion T3 to the second stacked portion T2) in the stacked body 20, the second columnar bodies CL2_1 are not provided in the third stacked portion T3.

In a case where the uppermost stacked portion of the stacked body 20 is the second stacked portion T2, the second columnar bodies CL2_1 are not provided in the second stacked portion T2. That is, in a case where a plurality of the electrode films 21 and a plurality of the insulating films 22 stacked in the Z direction are not included in the −Z direction of the second stacked portion T2 (on the opposite side of the second stacked portion T2 to the first stacked portion T1) in the stacked body 20, the second columnar bodies CL2_1 are not provided in the second stacked portion T2.

Furthermore, the second columnar bodies CL2_2 are not provided at the same height level as that of the third stacked portion T3 being the uppermost stacked portion of the stacked body 20 in the kerf region Kf. That is, in a case where a plurality of the electrode films 21 and a plurality of the insulating films 22 stacked in the Z direction are not included in the −Z direction of the third stacked portion T3 (on the opposite side of the third stacked portion T3 to the second stacked portion T2) in the stacked body 20, the second columnar bodies CL2_2 are not provided in a structure located alongside the third stacked portion T3 in the X or Y direction in the kerf region Kf.

In a case where the uppermost stacked portion in the stacked body 20 is the second stacked portion T2, the second columnar bodies CL2_2 are not provided at the same height level as that of the second stacked portion T2 in the kerf region Kf. That is, in a case where a plurality of the electrode films 21 and a plurality of the insulating films 22 stacked in the Z direction are not included in the −Z direction of the second stacked portion T2 (on the opposite side of the second stacked portion T2 to the first stacked portion T1) in the stacked body 20, the second columnar bodies CL2_2 are not provided in a structure located alongside the second stacked portion T2 in the X or Y direction in the kerf region Kf.

The supporting columns HR_1 to HR_3 are provided between the memory cell array 2m and the kerf region Kf to extend in the Z direction at the stepped portions 2s around the memory cell array 2m. For example, plural sets of the supporting columns HR_1 to HR_3 are regularly arranged at the stepped portions 2s. The supporting columns HR_1 to HR_3 support the insulating films 22 to prevent the stacked body 20 from caving in at the stepped portions 2s in the process of replacing the sacrificial films 21a of the stacked body 20 with the electrode films 21. The supporting columns HR_1 to HR_3 are constituted of an insulating material such as a silicon oxide. The supporting columns HR_1 to HR_3 can be formed by selectively embedding the insulating material in holes formed at the same time as the memory holes of the first to third stacked portions T1 to T3, respectively.

A manufacturing method of the semiconductor storage device 1 is explained next.

FIGS. 6A to 15 are sectional views illustrating one example of the manufacturing method of the semiconductor storage device 1 according to the first embodiment.

First, a conductive layer CND1 is formed above a substrate SUB. The substrate SUB can be, for example, a semiconductor substrate such as a silicon substrate. For example, a conductive material such as doped silicon is used as the conductive layer CND1.

Next, a sacrificial film SAC1 is formed on the conductive layer CND1. For example, a laminated film including a silicon dioxide film, a silicon nitride film and a silicon dioxide film is used as the sacrificial film SAC1. In the kerf region Kf, a silicon dioxide film is selectively formed on the conductive layer CND1 using a lithography technique and an etching technique.

Next, a conductive layer CND2 is formed on the sacrificial film SAC1 and the silicon dioxide film. For example, a conductive material such as doped silicon is used as the conductive layer CND2.

Next, the sacrificial films 21a and the insulating films 22 are alternately stacked on the conductive layer CND2 in the −Z direction to form the first stacked portion T1. At this stage, the first stacked portion T1 is a stacked body including the sacrificial films 21a and the insulating films 22. For example, a silicon nitride film is used as the sacrificial films 21a. For example, a silicon dioxide film is used as the insulating films 22.

Next, although not illustrated in FIG. 6A, end parts of the first stacked portion T1 are processed using a lithography technique and an etching technique to form the stepped portions 2s illustrated in FIG. 5A. The whole or a part of the first stacked portion T1 in the kerf region Kf is removed.

Next, the interlayer dielectric film 25 is deposited on the first stacked portion T1 and the conductive layer CND2 to fill a portion from which the first stacked portion T1 has been removed at the stepped portions 2s at the end parts of the first stacked portion T1 and in the kerf region Kf. For example, a silicon dioxide film is used as the interlayer dielectric film 25. A structure illustrated in FIG. 6A is thereby obtained.

Next, holes LHhr to be used for the supporting columns HR_1 are formed to penetrate through the interlayer dielectric film 25 and the first stacked portion T1 at the stepped portions 2s using a lithography technique and an etching technique. Next, the material (for example, a silicon oxide) of the supporting columns HR_1 is formed in the holes LHhr. A structure illustrated in FIG. 6B is thereby obtained.

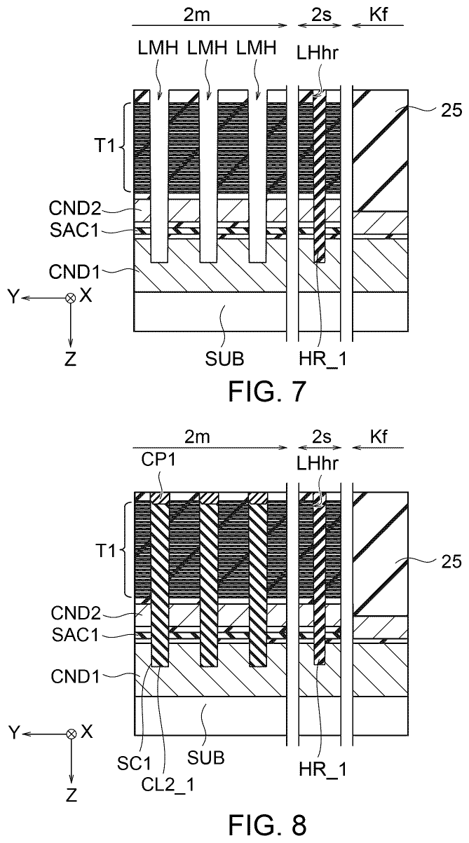

Next, as illustrated in FIG. 7, a plurality of memory holes LMH penetrating through the first stacked portion T1, the conductive layer CND2, and the sacrificial film SAC1 in the Z direction are formed using a lithography technique and an etching technique. The memory holes LMH as first holes reach the conductive layer CND1.

Next, as illustrated in FIG. 8, a sacrificial material is formed on the first stacked portion T1 and in the memory holes LMH. For example, a carbon material that can be selectively etched with respect to a silicon nitride film, a silicon dioxide film, and polysilicon is used as the sacrificial material.

Next, the sacrificial material on the first stacked portion T1 is etched back using an RIE (Reactive Ion Etching) method or the like. At this time, the sacrificial material on the first stacked portion T1 is removed using an EPD (End Point Detector). The sacrificial material in upper parts of the memory holes LMH is also etched to some extent, and the upper surface of the sacrificial material is etched to a position lower than the upper surfaces of the memory holes LMH, whereby the pillar portions SC1 are formed. A depressed area is formed at the upper end of each of the pillar portions SC1.

Next, the first material of the cap film CP1 is deposited on the first stacked portion T1, and the first material of the cap film CP1 is etched back by an RIE method or the like. Accordingly, the cap film CP1 is filled in the depressed areas on the pillar portions SC1 in the memory holes LMH. A structure illustrated in FIG. 8 is thereby obtained.

Next, the second stacked portion T2 is formed by alternately stacking the sacrificial films 21a and the insulating films 22 in the −Z direction on the first stacked portion T1 where the carbon material as the pillar portion SC1 and the first material as the cap film CP1 are formed in each of the memory holes LMH. The second stacked portion T2 is a stacked body including the sacrificial films 21a (for example, silicon nitride films) and the insulating films 22 (for example, silicon dioxide films).

Next, end parts of the second stacked portion T2 are processed using a lithography technique and an etching technique to form the stepped portions 2s illustrated in FIG. 5A at the end parts of the second stacked portion T2. At this time, a part of the second stacked portion T2 in the kerf region Kf may be removed.

Next, the interlayer dielectric film 25 is deposited on the second stacked portion T2 to fill a portion from which the second stacked portion T2 has been removed at the stepped portions 2s at the end parts of the second stacked portion T2 and in the kerf region Kf.

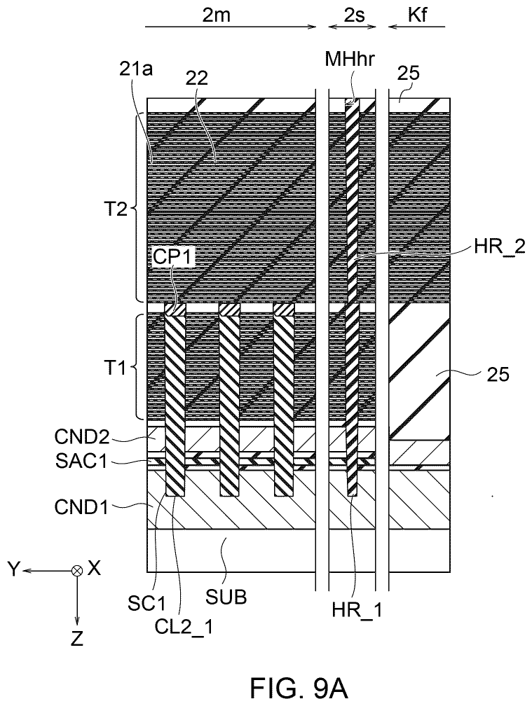

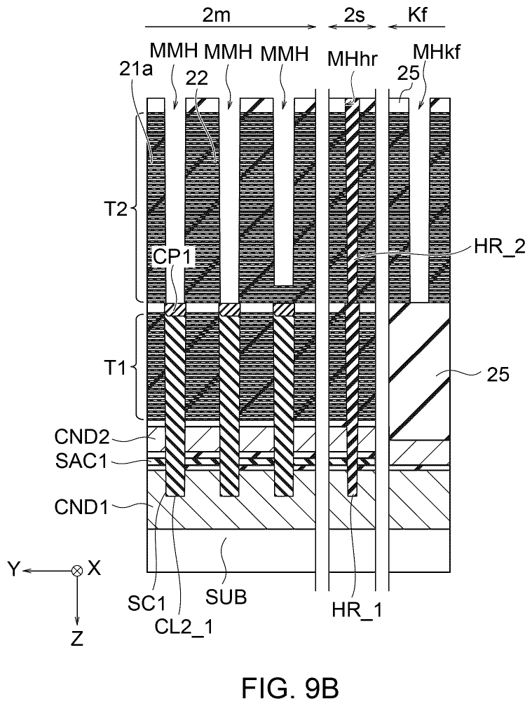

Next, holes MHhr to be used for the supporting columns HR_2 are formed to penetrate through the interlayer dielectric film 25 and the second stacked portion T2 at the stepped portions 2s using a lithography technique and an etching technique. The material (for example, a silicon oxide) of the supporting columns HR_2 is formed in the holes MHhr. The supporting columns HR_2 are formed on the supporting columns HR_1. A structure illustrated in FIG. 9A is thereby obtained.

Next, as illustrated in FIG. 9B, a plurality of memory holes MMH penetrating through the second stacked portion T2 in the Z direction are formed using a lithography technique and an etching technique. The memory holes MMH as second holes respectively correspond to the memory holes LMH, and are formed immediately above the corresponding memory holes LMH. The memory holes MMH are communicated with the corresponding memory holes LMH and reach the cap film CP1.

However, some of the memory holes MMH accidentally do not reach the memory holes LMH located therebelow in some cases. In these cases, the lower ends of some of the memory holes MMH remain in the middle of the second stacked portion T2 and do not reach the cap film CP1 as illustrated in FIG. 9B. In FIG. 9B, the second stacked portion T2 and the holes MHkf are formed also in the kerf region Kf.

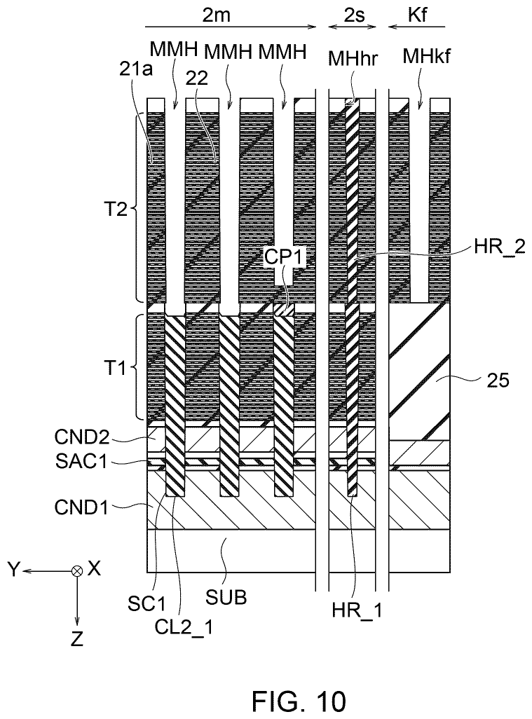

Next, as illustrated in FIG. 10, the first material of the cap film CP1 in the memory holes LMH is selectively removed through the memory holes MMH using a wet etching method. At this time, the material having an etching selectivity to the sacrificial films 21a (for example, silicon nitride films), the insulating films 22 (for example, silicon dioxide films), and the pillar portions SC1 (for example, carbon) is used as the cap film CP1. Therefore, the cap film CP1 can be selectively etched with respect to the sacrificial films 21a, the insulating films 22, and the carbon material of the pillar portions SC1.

Meanwhile, in a case where the lower ends of the memory holes MMH do not reach the cap film CP1, the first material of the cap film CP1 remains without being removed. In the kerf region Kf, the interlayer dielectric film 25 is exposed on the bottom parts of the holes MHkf. Since the interlayer dielectric film 25 is, for example, a silicon dioxide film, the interlayer dielectric film 25 is not etched in this process. Although not illustrated, in another region of the kerf region Kf, it is possible that the first stacked portion T1 and holes are provided and that the pillar portion SC1 and the cap film CP1 are provided in each of the holes similarly to the memory cell array 2m.

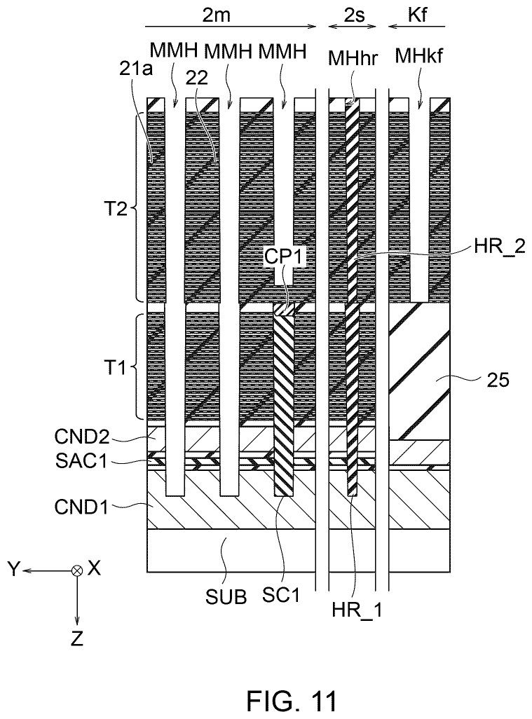

Next, as illustrated in FIG. 11, the carbon material of the pillar portions SC1 in the memory holes LMH is removed through the memory holes MMH by ashing processing. Meanwhile, the carbon material of the pillar portions SC1 located immediately below the memory holes MMH that do not reach the cap film CP1 is left. In the kerf region Kf, the interlayer dielectric film 25 at the bottom parts of the holes MHkf is not removed by ashing because it is, for example, a silicon dioxide film.

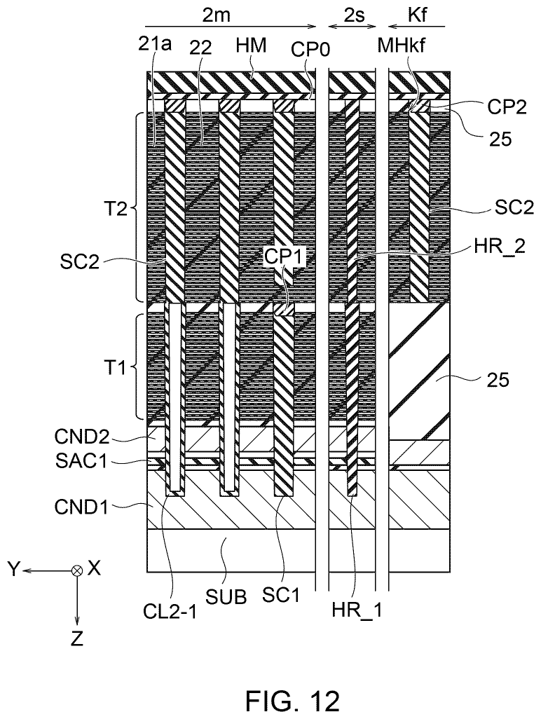

Next, as illustrated in FIG. 12, a sacrificial material is formed on the second stacked portion T2 and in the memory holes LMH and MMH and the holes MHkf. For example, a carbon material that can be selectively etched with respect to a silicon nitride film, a silicon dioxide film, and polysilicon is used as the sacrificial material.

Next, the sacrificial material on the second stacked portion T2 is etched back using an RIE method or the like. At this time, the sacrificial material on the second stacked portion T2 is removed using an EPD. The sacrificial material in upper parts of the memory holes MMH and the holes MHkf is also etched to some extent and the upper surface of the sacrificial material is etched to a position lower than the upper surfaces of the memory holes MMH, whereby the pillar portions SC2 are formed. A depressed area is formed at the upper end of each of the pillar portions SC2.

Next, the second material of the cap film CP2 is deposited on the second stacked portion T2 and the second material of the cap film CP2 is etched back by an RIE method or the like. Accordingly, the cap film CP2 is embedded in the depressed areas on the pillar portions SC2 in the memory holes MMH and the holes MHkf. The second material of the cap film CP2 can be the same as the first material of the cap film CP1.

Next, a cap film CP0 and a mask material HM are formed on the interlayer dielectric film 25 deposited on the second stacked portion T2. For example, an insulating material such as a silicon dioxide film is used as the cap film CP0. For example, a material such as amorphous silicon having an etching selectivity to the interlayer dielectric film 25 (for example, a silicon dioxide film) is used as the mask material HM. At this time, the pillar portions SC2 are annealed by thermal treatment. There is a case where the pillar portions SC2 are contracted by this annealing. However, since a material higher in the density than the sacrificial films 21a (for example, a silicon nitride), the insulating films 22 (for example, a silicon oxide), and the pillar portions SC1 (for example, carbon) is used as the second material of the cap film CP2, the cap film CP2 is not as contracted as the pillar portions SC2 and is in close contact with the inner wall of each of the holes MHkf.

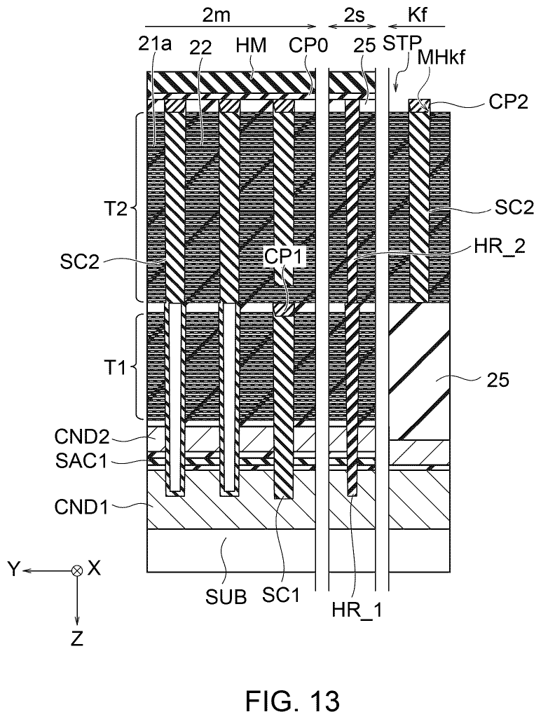

Next, the mask material HM and the cap film CP0 in the kerf region Kf are selectively removed using a lithography technique and an etching technique. Further, an upper part of the interlayer dielectric film 25 as a third insulating film is etched using the mask material HM as a mask. Accordingly, as illustrated in FIG. 13, a step STP associated with each of the holes MHkf is formed in the kerf region Kf. The steps STP are used as alignment marks when memory holes UMH are thereafter formed.

At this time, even when the pillar portion SC2 is contracted by the annealing and a gap is formed between the pillar portion SC2 and the inner wall of each of the holes MHkf, the cap film CP2 is not contracted so much and is in close contact with the upper surface of the pillar portion SC2 and the inner wall of each of the holes MHkf. Accordingly, the cap film CP2 can suppress collapse of the pillar portion SC2.

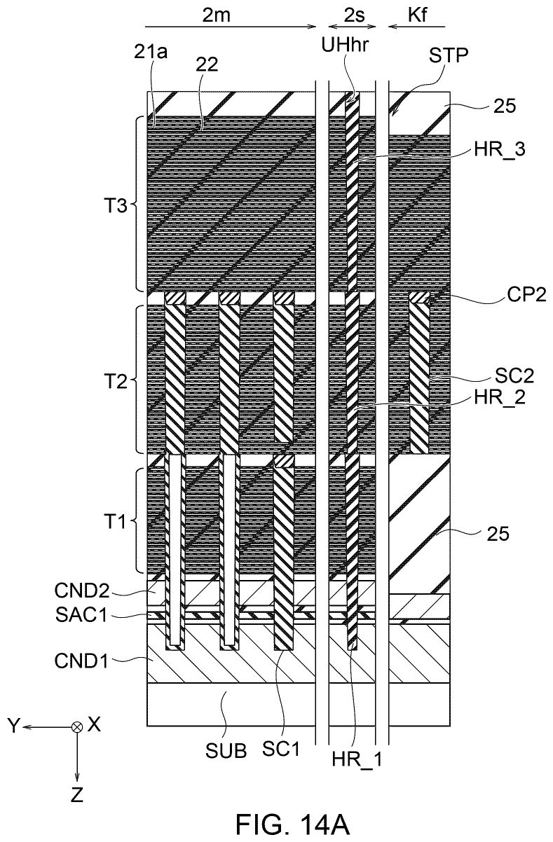

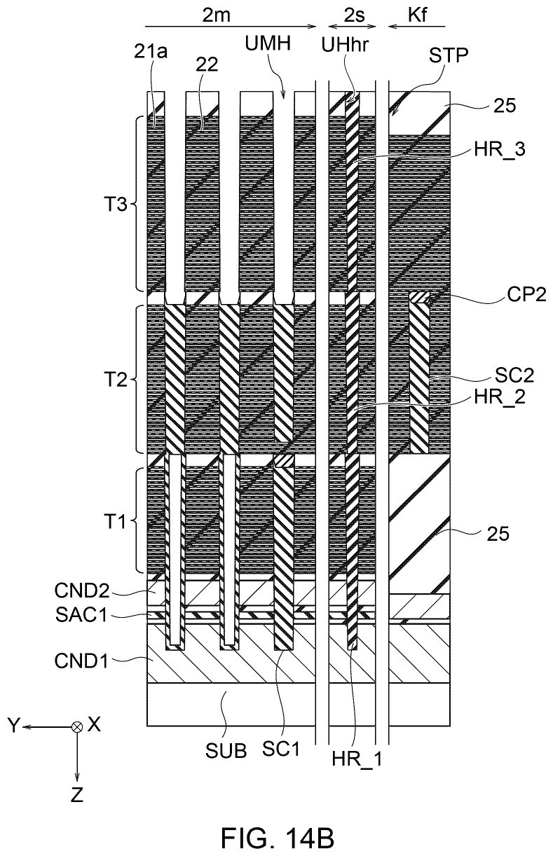

The mask material HM is thereafter removed. However, the cap film CP0 is left on the interlayer dielectric film 25. Since the cap film CP0 is constituted of, for example, a silicon dioxide film similarly to the interlayer dielectric film 25, illustrations of the cap film CP0 are omitted in some of FIG. 14A and the subsequent drawings.

In FIGS. 8 to 9B, steps functioning as alignment marks may be provided in the kerf region Kf in the first stacked portion T1 to form the memory holes MMH in the second stacked portion T2. In this case, the cap film CP0 is left between the first stacked portion T1 and the second stacked portion T2 and illustrations thereof are similarly omitted in some drawings as described above.

Next, after the mask material HM is removed, the third stacked portion T3 is formed by alternately stacking the sacrificial films 21a and the insulating films 22 in the −Z direction on the second stacked portion T2 where the carbon material as the pillar portion SC2 and the second material as the cap film CP2 are formed as illustrated in FIG. 14A. The third stacked portion T3 is a stacked body including the sacrificial films 21a (for example, silicon nitride films) and the insulating films 22 (for example, silicon dioxide films). At this time, the steps STP on the second stacked portion T2 are transferred also onto the third stacked portion T3.

Next, although not illustrated in FIG. 14A, end parts of the third stacked portion T3 are processed using a lithography technique and an etching technique to form the stepped portions 2s illustrated in FIG. 5A at the end parts of the third stacked portion T3. At this time, a part of the third stacked portion T3 in the kerf region Kf may be removed although not illustrated.

Next, the interlayer dielectric film 25 is deposited on the third stacked portion T3 to fill a portion from which the third stacked portion T3 has been removed at the stepped portions 2s at the end parts of the third stacked portion T3 and in the kerf region Kf.

Next, holes UHhr to be used for the supporting columns HR_3 are formed to penetrate through the interlayer dielectric film 25 and the third stacked portion T3 at the stepped portions 2s using a lithography technique and an etching technique. The material (for example, a silicon oxide) of the supporting columns HR_3 is formed in the holes UHhr. The supporting columns HR_3 are formed on the supporting columns HR_2. A structure illustrated in FIG. 14A is thereby obtained.

Next, as illustrated in FIG. 14B, a plurality of memory holes UMH penetrating through the third stacked portion T3 in the Z direction are formed using a lithography technique and an etching technique. At this time, the steps STP are used as alignment marks. Therefore, the memory holes UMH as third holes respectively correspond to the memory holes LMH and MMH, and can be formed immediately above the corresponding memory holes LMH and MMH. The memory holes UMH are communicated with the corresponding memory holes MMH and reach the cap film CP2. The memory holes UMH, MMH, and LMH substantially overlap with each other when seen in the Z direction.

Next, as illustrated in FIG. 14B, the second material of the cap film CP2 in the memory holes MMH is selectively removed through the memory holes UMH using a wet etching method. A material having an etching selectivity to the sacrificial films 21a (for example, silicon nitride films), the insulating films 22 (for example, silicon dioxide films), and the pillar portions SC2 (for example, carbon) is used as the cap film CP2. Therefore, the cap film CP2 can be selectively etched with respect to the sacrificial films 21a, the insulating films 22, and the carbon material of the pillar portions SC2.

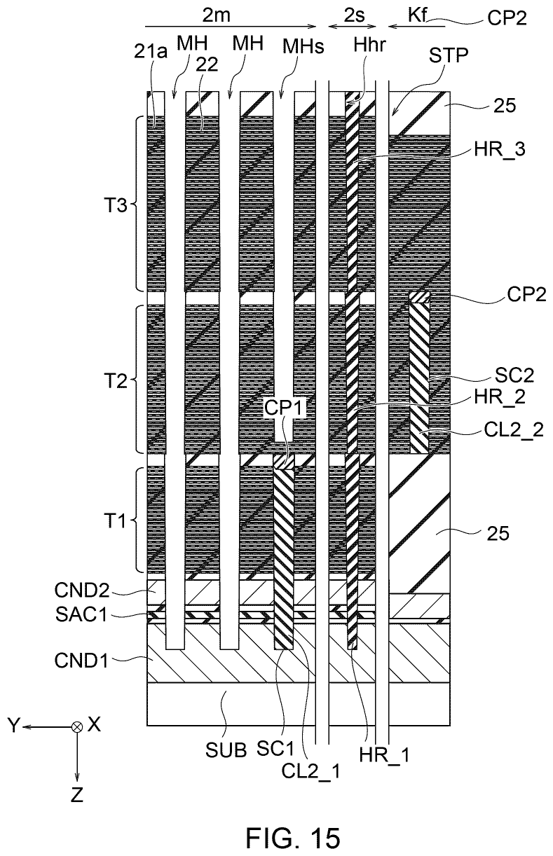

Next, as illustrated in FIG. 15, the carbon materials of the pillar portions SC1 and SC2 in the memory holes LMH and MMH are removed through the memory holes UMH by ashing processing.

In the memory cell array 2m, the memory holes UMH, MMH, and LMH communicated with each other constitute one memory hole MH. The memory holes UMH and MMH located above the second columnar bodies CL2_1 of the first stacked portion T1 constitute memory holes MHs shallower than the memory holes MH.

Next, the first columnar bodies CL1 in FIG. 5A are formed in the memory holes MH and MHs of the memory cell array 2m using a lithography technique and a film formation technique.

Next, the slits ST in FIG. 2 are formed to penetrate through the stacked body 20 in the Z direction to reach the sacrificial film SAC1. The sacrificial film SAC1 is removed through the slits ST and the memory film 220 on the outer circumference of each of the first columnar bodies CL1 is further removed to expose the semiconductor body 210. Next, the source layer BSL is formed by embedding the same conductive material as the conductive layers CND1 and CND2 in a space from which the sacrificial film SAC1 has been removed. The source layer BSL is in contact with the semiconductor bodies 210 and is electrically connected thereto.

Next, the sacrificial films 21a are removed through the slits ST. Next, the material (for example, tungsten) of the electrode films 21 is embedded through the slits ST in spaces from which the sacrificial films 21a have been removed. For example, a conductive material such as tungsten is used as the material of the electrode films 21. In this way, the sacrificial films 21a are replaced by the electrode films 21 (the replacement process).

Subsequently, at the stepped portions 2s, the contact plugs CCw (see FIG. 1) each connecting to an electrode film 21 are formed, and the vias 28 or the lines 23 (see FIG. 1) each connecting to the semiconductor body 210 of a first columnar body CL1, and the like are formed. The array chip 2 illustrated in FIG. 1 is thereby formed.

Meanwhile, the CMOS chip 3 is formed on another semiconductor substrate. The array chip 2 and the CMOS chip 3 are bonded to each other as illustrated in FIG. 1, and the back surface of the array chip 2 is polished. The metallic layer 40 and the bonding pads 50 are formed above the source layer BSL, whereby the semiconductor storage device 1 illustrated in FIG. 1 is completed.

### (Effects of Cap Film CP1)

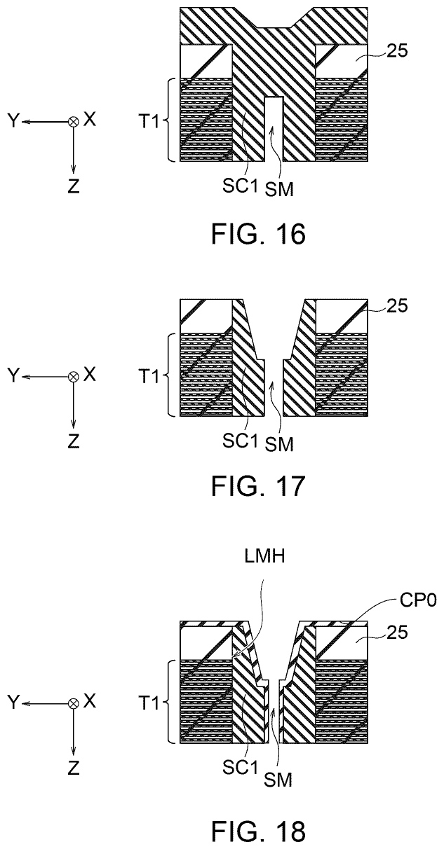

FIGS. 16 to 20 are sectional views illustrating a manufacturing method of a semiconductor storage device in a case where the cap film CP1 is not used.

As illustrated in FIG. 16, when the sacrificial material to be used for the pillar portions SC1 is formed in the memory holes LMH, a seam or a void (hereinafter, simply “seam”) SM is sometimes generated in the sacrificial material. In this case, as illustrated in FIG. 17, when the sacrificial material is etched back by an RIE method, one end of the sacrificial material in the −Z direction is scraped, the depressed area of the sacrificial material is communicated with the seam SM, and the seam SM adversely leads to the outside.

Next, when the cap film CP0 (for example, a silicon dioxide film) is deposited, the cap film CP0 enters the inside of the seam SM and is formed as a film on the inner wall of the sacrificial material (the pillar portions SC1) in the memory holes LMH as illustrated in FIG. 18.

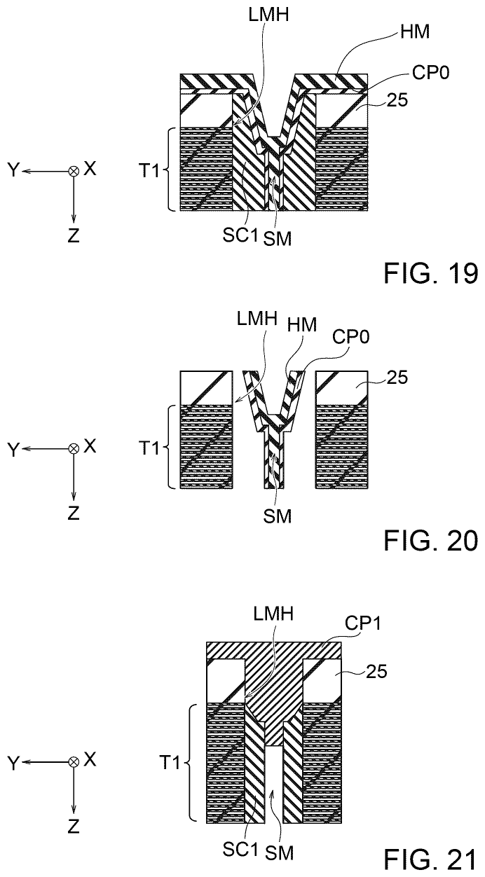

Next, the mask material HM covering the memory cell array 2m is deposited on the cap film CP0 for formation of alignment marks. At this time, as illustrated in FIG. 19, the mask material HM also enters the seam SM.

Next, as explained with reference to FIG. 13, after the interlayer dielectric film 25 is processed using the mask material HM as a mask, the mask material HM is removed. However, the mask material HM in the seam SM remains.

When the sacrificial material (for example, carbon) of the pillar portions SC1 is thereafter removed, there is a case where the mask material HM and the material (for example, a silicon oxide) of the cap film CP0 remain in the memory holes LMH as illustrated in FIG. 20. In this case, if removal of the material of the remaining cap film is attempted, the insulating films 22 in the first stacked portion T1 are also removed. Therefore, the cap film CP0 in each of the memory holes LMH cannot be removed. That is, it is difficult to form the semiconductor body 210, the memory film 220, and the like in each of the memory holes LMH. This is a problem that may occur similarly in the second staked portion T2 located under the uppermost stacked portion (the third stacked portion T3).

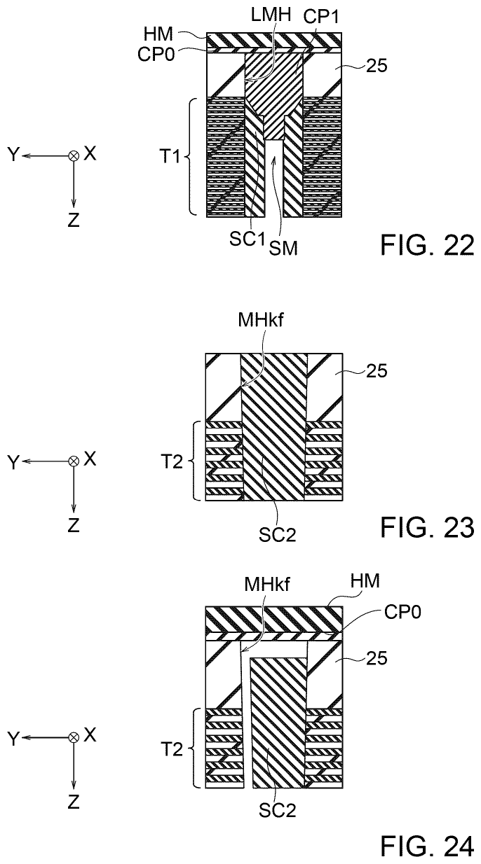

FIGS. 21 and 22 are sectional views illustrating one example of a manufacturing method of a semiconductor storage device in a case where the cap film CP1 according to the first embodiment is used. In contrast to the example illustrated in FIGS. 16 to 20, according to the present embodiment, as illustrated in FIG. 8, after the pillar portion SC1 is formed in the memory holes LMH, the cap film CP1 (for example, amorphous silicon) is embedded in the depressed areas at the upper ends of the pillar portions SC1. At this time, it suffices that the first material of the cap film CP1 is formed by, for example, a deposition method that is low in coverage, such as PE-CVD (Plasma Enhanced Chemical Vapor Deposition). This causes the first material of the cap film CP1 to remain at an upper part of the seam SM without entering a lower part of the seam SM.

Next, the first material of the cap film CP1 on the interlayer dielectric film 25 is etched back. The cap film CP1 fills the depressed areas at the upper ends of the pillar portions SC1 and slightly enters the upper end of the seam SM. Accordingly, the cap film CP1 is chemically and physically in close contact with the pillar portions SC1. Therefore, as illustrated in FIG. 22, for example, the cap film CP0 and the mask material HM that cover the memory cell array 2m for formation of alignment marks do not enter the seam SM.

The cap film CP1 has an etching selectivity to the pillar portions SC1 (for example, carbon), the insulating films 22 (for example, silicon dioxide films), and the sacrificial films 21a (for example, silicon nitride films). Therefore, as illustrated in FIG. 9B, the cap film CP1 can function as an etching stopper when the insulating films 22 and the sacrificial films 21a of the second stacked portion T2 are selectively processed to form the memory holes MMH. Accordingly, the memory holes MMH can be easily formed as designed. Furthermore, at the time of removal of the cap film CP1, the cap film CP1 can be selectively removed with respect to the pillar portions SC1, the insulating films 22, and the sacrificial films 21a. This enables the pillar portions SC1 in the memory holes LMH to be removed through the memory holes MMH while the opening diameter of the memory holes MMH is kept as illustrated in FIG. 11.

For example, a carbon material is used as the sacrificial material of the pillar portions SC1. If the pillar portions SC1 are constituted of, for example, amorphous silicon that is the same as the cap film CP1, amorphous silicon does not have a prominent etching selectivity to a silicon dioxide film and a silicon nitride film constituting the insulating films 22 and the sacrificial films 21a, relative to the carbon material. Therefore, there is a risk that the opening diameter of the memory holes LMH is not formed as designed or that the material of the pillar portions SC1 remains in the memory holes LMH when the pillar portions SC1 are removed.

In contrast thereto, according to the present embodiment, the pillar portion SC1 under the cap film CP1 is constituted of a carbon material having a prominent etching selectivity to a silicon dioxide film and a silicon nitride film. Accordingly, at the time of removal of the pillar portions SC1, the opening diameter of the memory holes LMH is easily controlled and the carbon material of the pillar portion SC1 can be surely removed from the memory holes LMH.

### (Effects of Cap Film CP2)

FIGS. 23 to 25 are sectional views illustrating a manufacturing method of a semiconductor storage device in a case where the cap film CP2 is not used for formation of the second stacked portion T2. FIGS. 23 to 25 illustrate the second stacked portion T2 in the kerf region Kf.

As illustrated in FIG. 23, the pillar portions SC2 are formed in the holes MHkf in the kerf region Kf.

Next, as illustrated in FIG. 24, the cap film CP0 and the mask material HM are deposited on the second stacked portion T2. At this time, as illustrated in FIG. 24, the carbon material of the pillar portions SC2 is annealed by thermal treatment and is contracted.

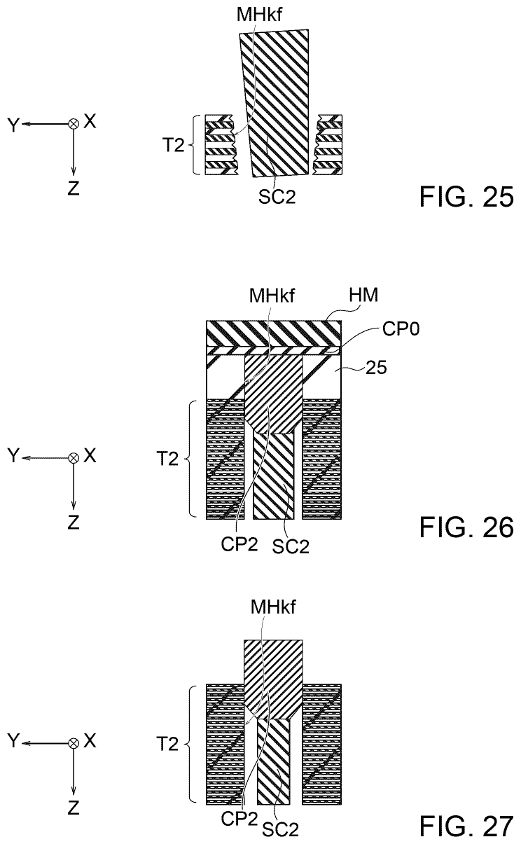

Next, when the mask material HM, the cap film CP0, and at least an upper part of the interlayer dielectric film 25 are selectively removed to form alignment marks, a gap is formed between each of the pillar portions SC2 and the inner wall of the associated hole MHkf as illustrated in FIG. 25, and there is a risk that the pillar portions SC2 fall.

FIGS. 26 and 27 are sectional views illustrating one example of a manufacturing method of a semiconductor storage device in a case where the cap film CP2 according to the first embodiment is used. FIGS. 26 and 27 illustrate the second stacked portion T2 in the kerf region Kf. In contrast to the example illustrated in FIGS. 23 to 25, according to the present embodiment, after the pillar portions SC2 are formed in the holes MHkf, the cap film CP2 (for example, amorphous silicon) is embedded in the depressed area on the upper end of each of the pillar portions SC2. The depressed area is provided to reach a position lower than steps provided to form alignment marks. In this case, the cap film CP2 is in an upper part of each of the holes MHkf also after the steps are provided in the kerf region Kf. As illustrated in FIG. 26, even when the carbon material of the pillar portions SC2 is contracted by annealing, the second material of the cap film CP2 is higher in the density than the carbon material of the pillar portions SC2 and is contracted less than the pillar portions SC2. Therefore, even when each of the pillar portions SC2 is separated from the inner wall of the associated hole MHkf, the cap film CP2 is in contact with the inner wall of the hole MHkf.

Next, the mask material HM and the cap film CP0 in the kerf region Kf are selectively removed to form alignment marks. Next, an upper part of the interlayer dielectric film 25 in the kerf region Kf is removed using the mask material HM as a mask. A structure illustrated in FIG. 27 is thereby obtained. The cap film CP2 fills the depressed area at the upper end of each of the pillar portions SC2 and is lower in heat contraction than the pillar portions SC2. Therefore, even when a gap is generated between each of the pillar portions SC2 and the associated hole MHkf, the cap film CP2 is in close contact with the upper surface of the pillar portion CP2 and the inner wall of the hole MHkf. Accordingly, the cap film CP2 can suppress collapse of the pillar portion SC2. As a result, in the present embodiment, the alignment marks can be easily formed and the semiconductor storage device 1 that is highly reliable can be formed.

### Second Embodiment

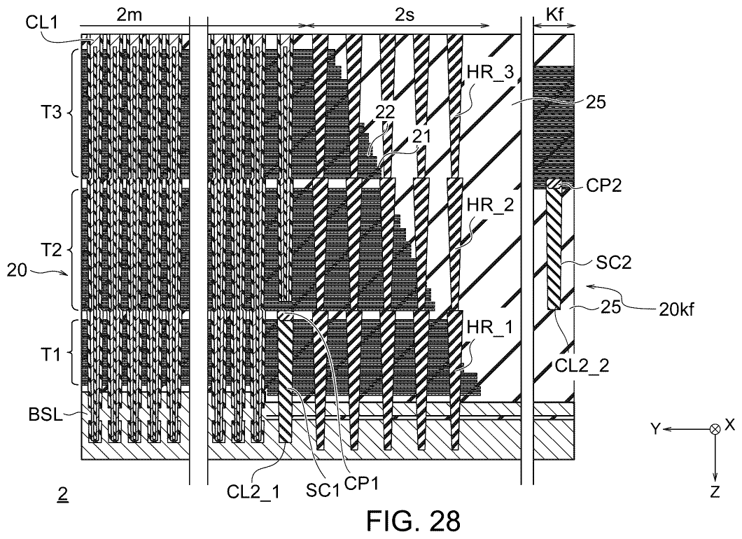

FIG. 28 is a sectional view illustrating a configuration example of the array chip 2 according to a second embodiment. In the second embodiment, the second columnar bodies CL2_2 in the kerf region Kf are provided in the interlayer dielectric film 25 (for example, a silicon dioxide film) adjacent to the second stacked portion T2. In the kerf region Kf, there is a portion where no stacked body is arranged and where a single film of the interlayer dielectric film is provided. The second columnar bodies CL2_2 may be provided in this single film of the interlayer dielectric film 25. That is, the second columnar bodies CL2_2 are provided to penetrate in the Z direction through the single film of the interlayer dielectric film 25 provided alongside the second stacked portion T2 in the X or Y direction. In this case, the structures 20kf are the interlayer dielectric film 25. The interlayer dielectric film 25 can be a silicon dioxide film formed using, for example, TEOS (Tetra Ethoxy Silane) or the like. The second columnar bodies CL2_2 can be used as alignment marks at the time of formation of the memory holes UMH.

Other configurations of the second embodiment may be identical to those of the first embodiment. Therefore, the second embodiment can attain identical effects as those of the first embodiment.

### Third Embodiment

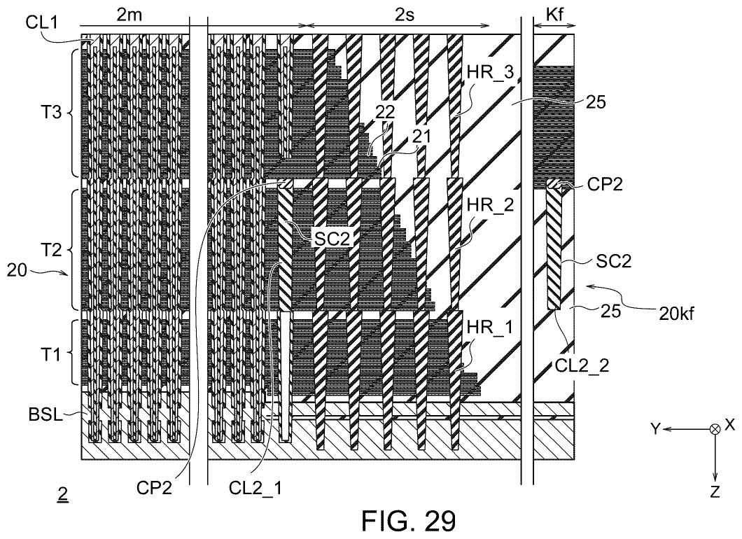

FIG. 29 is a sectional view illustrating a configuration example of the array chip 2 according to a third embodiment. In the third embodiment, the second columnar bodies CL2_1 are provided in the second stacked portion T2 and the first stacked portion T1.

Memory holes for the second columnar bodies CL2_1 formed in the second stacked portion T2 may not be communicated with the memory holes in the third stacked portion T3 located immediately thereabove. Therefore, the first columnar bodies CL1 are not formed in the memory holes for the second columnar bodies CL2_1 in the second stacked portion T2 and the first stacked portion T1 located thereunder, and the pillar portion SC2 and the cap film CP2 remain therein. In this way, the second columnar bodies CL2_1 can be formed also in the second stacked portion T2 and the first stacked portion T1 communicated with each other. Accordingly, the third embodiment can attain the effects explained with reference to FIGS. 21 and 22 also in the second stacked portion T2.

Other configurations of the third embodiment may be identical to those of the first or second embodiment. Therefore, the third embodiment can attain identical effects as those of the first or second embodiment even though the configuration of the second columnar bodies CL2_1 is different from that of the first or second embodiment.

### Fourth Embodiment

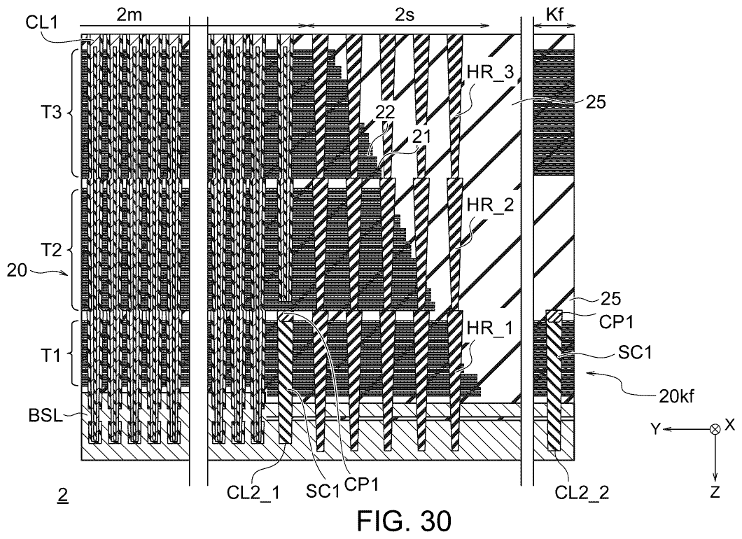

FIG. 30 is a sectional view illustrating a configuration example of the array chip 2 according to a fourth embodiment. In the fourth embodiment, the second columnar bodies CL2_2 are arranged in the structures 20kf that are provided at the same height level as that of the first stacked portion T1 in the Z direction. That is, the second columnar bodies CL2_2 are arranged to penetrate in the Z direction through the structures 20kf provided alongside the first stacked portion T1 in the X or Y direction. The second columnar bodies CL2_2 can be used as alignment marks at the time of formation of the memory holes MMH.

Other configurations of the fourth embodiment may be identical to those of the first embodiment. Therefore, the fourth embodiment can attain identical effects as those of the first embodiment even though the location of the second columnar bodies CL2_2 is different from that of the first embodiment.

The structures 20kf may be stacked bodies each including the sacrificial films 21a before being replaced with the electrode films 21 and the insulating films 22, or may be stacked bodies each including the electrode films 21 after replacement and the insulating films 22.

### Fifth Embodiment

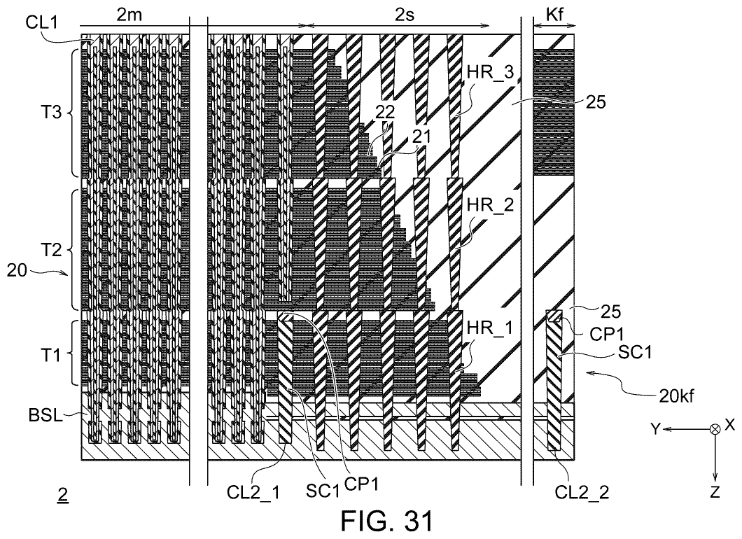

FIG. 31 is a sectional view illustrating a configuration example of the array chip 2 according to a fifth embodiment. In the fifth embodiment, the second columnar bodies CL2_2 are arranged in a single film of the interlayer dielectric film 25 that is at the same height level as that of the first stacked portion T1 in the Z direction. That is, the second columnar bodies CL2_2 are arranged to penetrate in the Z direction through the single film (a first structure portion) of the interlayer dielectric film 25 provided alongside the first staked portion T1 in the X or Y direction. The second columnar bodies CL2_2 can be used as alignment marks at the time of formation of the memory holes MMH.

Other configurations of the fifth embodiment may be identical to those of the fourth embodiment. Therefore, the fifth embodiment can attain identical effects as those of the fourth embodiment.

The number of stacked portions constituting the stacked body 20 may be four or more. In this case, the second columnar bodies CL2_1 can be formed in a stacked portion other than the uppermost one in the stacked body 20. The second columnar bodies CL2_2 can be formed in the kerf region Kf alongside a stacked portion other than the uppermost one in the stacked body 20 in the X or Y direction.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor storage device comprising:
a stacked body including a plurality of electrode films and a plurality of first insulating films alternately stacked in a first direction;
a plurality of first columnar bodies each comprising a semiconductor layer located to penetrate through the stacked body in the first direction and forming a memory cell at an intersecting portion with one of the electrode films;
a source layer electrically connected to an end part of the semiconductor layer on a side of one end out of one end and another end of the semiconductor layer in the first direction;
a pillar portion located to extend in the first direction in the stacked body, or in a structure located alongside the stacked body in a second direction intersecting with the first direction, and comprising a carbon material; and
a cap portion located at an end part of the pillar portion on a side of another end out of one end and another end of the pillar portion respectively corresponding to the one end and the other end of the semiconductor layer in the first direction, and comprising a first material having an etching selectivity to at least the carbon material and the first insulating films.

2. The device of claim 1, wherein the first material is higher in density than at least the carbon material.

3. The device of claim 1, wherein the first material is higher in density than carbon, a silicon oxide, and a silicon nitride.

4. The device of claim 1, wherein the first material comprises any material of a metal, a metallic compound, a semiconductor, and ceramics.

5. The device of claim 1, wherein the first material comprises any material of amorphous silicon, polysilicon, BC, WC, WBC, W, TiN, Mo, MoC, and AlO.

6. The device of claim 1, wherein the stacked body is located in a memory cell array region, the structure is located in an outer edge region around the memory cell array region, and the pillar portion and the cap portion are located in the structure when seen in the first direction.

7. The device of claim 1, wherein the pillar portion and the cap portion are located in the stacked body.

8. The device of claim 7, wherein the first columnar bodies are regularly provided in a first region in the stacked body, and the pillar portion and the cap portion are provided in a second region outside the first region in the stacked body when seen in the first direction.

9. The device of claim 1, wherein
the stacked body comprises a first stacked portion and a second stacked portion each comprising the electrode films and the first insulating films stacked in the first direction,
the first stacked portion is located between the source layer and the second stacked portion in the first direction, and
the pillar portion and the cap portion are located to penetrate through the first stacked portion in the first direction.

10. The device of claim 9, wherein
the stacked body does not comprise the electrode films and the first insulating films stacked in the first direction on an opposite side of the second stacked portion to the first stacked portion in the first direction, and
the pillar portion and the cap portion are not located in the second stacked portion in the stacked body.

11. The device of claim 1, wherein
the stacked body comprises a first stacked portion and a second stacked portion each comprising the electrode films and the first insulating films stacked in the first direction,
the first stacked portion is located between the source layer and the second stacked portion in the first direction, and
the pillar portion and the cap portion are located to penetrate in the first direction through a first structure portion located alongside the first stacked portion in the second direction.

12. The device of claim 11, wherein the pillar portion and the cap portion are located to penetrate in the first direction through the first structure portion comprising the first insulating films and a plurality of second insulating films alternately stacked in the first direction.

13. The device of claim 11, wherein the pillar portion and the cap portion are located to penetrate in the first direction through the first structure portion being a single film of a third insulating film.

14. The device of claim 11, wherein
the stacked body does not comprise the electrode films and the first insulating films stacked in the first direction on an opposite side of the second stacked portion to the first stacked portion in the first direction, and
the pillar portion and the cap portion are not located in a second structure portion located alongside the second stacked portion in the second direction in the structure.

15. The device of claim 14, wherein the pillar portion and the cap portion are not located in at least the second stacked portion in the stacked body.

16. A manufacturing method of a semiconductor storage device, the method comprising:
forming a first stacked portion by alternately stacking a plurality of first sacrificial materials and a plurality of first insulating materials in a first direction;
forming a plurality of first holes penetrating through the first stacked portion in the first direction;
forming a first carbon material above the first stacked portion and in the first holes;
removing the first carbon material above the first stacked portion and in upper parts of the first holes;
forming a first cap portion on the first carbon material in each of the first holes;
forming a second stacked portion by alternately stacking the first sacrificial materials and the first insulating materials in the first direction above the first stacked portion including the first carbon material and the first cap portion formed in each of the first holes;
forming a plurality of second holes penetrating through the second stacked portion in the first direction, on the first holes, respectively;
selectively removing the first cap portion and the first carbon material in each of the first holes with respect to the first and second stacked portions, through the second holes; and
forming a plurality of first columnar bodies each comprising a semiconductor layer in the first and second holes.

17. The method of claim 16, further comprising:
after removing the first cap portion and the first carbon material,
forming a second carbon material above the second stacked portion and in the first and second holes;
removing the second carbon material above the second stacked portion and in upper parts of the second holes;
forming a second cap portion on the second carbon material in each of the second holes;
forming a third stacked portion by alternately stacking the first sacrificial materials and the first insulating materials in the first direction above the second stacked portion including the second carbon material and the second cap portion formed in each of the second holes;
forming a plurality of third holes penetrating through the third stacked portion in the first direction, on the second holes, respectively; and
selectively removing the second cap portion in each of the second holes and the second carbon material in each of the first and second holes with respect to the first to third stacked portions, through the third holes, wherein
the first columnar bodies are formed in the first to third holes.

18. The method of claim 16, wherein
the first holes, the first carbon material, and the first cap portion are formed in a first region where the first and second stacked portions are located, and a second region located around the first region when seen in the first direction, and
the first carbon material and the first cap portion in the second region are left at a time of selectively removing the first carbon material and the first cap portion through the second holes in the first region.

19. The method of claim 17, wherein
the second holes, the second carbon material, and the second cap portion are formed in a first region where the first to third stacked portions are located, and a second region located around the first region when seen in the first direction, and
the second carbon material and the second cap portion in the second region are left at a time of selectively removing the second carbon material and the second cap portion through the third holes in the first region.

20. The method of claim 19, further comprising:
forming an insulating film on the second stacked portion after forming the second stacked portion;
after forming the second carbon material and the second cap portion and before forming the third stacked portion, forming a mask material above the insulating film in the first region; and
selectively removing at least a part of the insulating film in the second region using the mask material as a mask.
